(19) United States
(12) Patent Application Publication
(10) Pub. No.: US 2026/0156790 A1
(43) Pub. Date: Jun. 4, 2026

(54) COOLING SYSTEM FOR AN AT LEAST PARTIALLY ELECTRIC MACHINE OR VEHICLE

(71) Applicant: Caterpillar Inc., Peoria, IL (US)

(72) Inventors: Noah GEORGE, Brimfield, IL (US); Craig P. HITTLE, Dunlap, IL (US)

(73) Assignee: Caterpillar Inc., Peoria, IL (US)

(21) Appl. No.: 18/965,302

(22) Filed: Dec. 2, 2024

(51) Int. Cl. H05K 7/20

(52) U.S. Cl. CPC H05K 7/20909; H05K 7/20145; H05K 7/20154; H05K 7/20945

(57) ABSTRACT

A cooling system for an at least partially electric machine or vehicle is described herein. The disclosure may include a machine including a hood, a power system, a power system cavity, a central chamber, and a divider positioned within the central chamber. The hood may include one or more air inlets and one or more air outlets. The power system may include one or more batteries, a power electronics module, and a secondary power source. The central chamber may be defined between the power electronics module and the secondary power source, and the central chamber may receive inflowing air via the one or more inlets. The divider may be configured to direct a portion of the inflowing air toward the power electronics module and another portion of the inflowing air toward the secondary power source. After cooling the secondary power source, inflowing air may exit via the air outlet(s).

### TECHNICAL FIELD

The present disclosure relates generally to at least partially machines or vehicles, and more particularly, to a cooling system for an at least partially electric machine or vehicle.

### BACKGROUND

Industrial vehicles or machines, for example, wheel loaders, excavators, trucks (e.g., dump trucks, haul trucks, articulated dump trucks, etc.), track-type tractors (e.g., bulldozers), graders, continuous miners, feeder breakers, roof bolters, utility vehicles for mining, load-haul-dump (LHD) vehicles, underground mining loaders, underground articulated trucks, etc., may be fully electric, semi-electric (e.g., at least partially electrical), and non-electric. Electric and semi-electric vehicles include one or more batteries, and non-electric vehicles can be retrofitted or upgraded to include one or more batteries. The one or more batteries include various connections (e.g., electrical connections) in order to power one or more motors, heating and/or cooling systems, hydraulic system(s), navigation systems, lighting systems, electronics, auxiliary systems, etc. However, the various components or the various systems often generate heat, and the heat generated during operation of a machine or vehicle may reduce the efficiency of the batteries, the various components, or the various systems.

U.S. Pat. No. 10,480,394, issued to Shi et al. on Jul. 21, 2020 (“the '394 patent”), describes a shroud of a heat exchange assembly of a vehicle. In particular, the shroud includes a ventilation aperture disposed on a housing of the shroud and two flow guide structures. The '394 patent discloses that the flow guide structure is configured to guide airflow from the ventilation aperture away from a clearance between the housing and a radiator of the heat exchange assembly to prevent recirculation of airflow. However, the flow guide structures of the '394 patent merely prevent recirculation of airflow by guiding airflow through ventilation apertures. The flow guide apertures of the '394 patent do not direct airflow over or around components of the heat exchange assembly to remove heat or otherwise help to thermally isolate various components or systems from other components or systems.

The cooling system of the present disclosure may solve one or more of the problems set forth above or other problems in the art. The scope of the current disclosure, however, is defined by the attached claims, and not by the ability to solve any specific problem.

### SUMMARY

Each of the aspects disclosed herein may include one or more features described in connection with any of the other disclosed aspects.

Aspects of the present disclosure include a machine. The machine comprises a machine body and a hood coupled to the machine body. The hood includes one or more air inlets and one or more air outlets. The machine further comprises a power system including one or more batteries, a power electronics module, and a secondary power source. The machine comprises a power system cavity defined between the hood and the machine body and configured to receive the power system. The machine also comprises a central chamber defined between the power electronics module and the secondary power source. The central chamber receives inflowing air via the one or more inlets. The machine comprises a divider positioned within the central chamber and configured to direct a portion of the inflowing air toward the power electronics module to cool the power electronics module. After cooling the power electronics module, inflowing air exits the power system cavity via the one or more air outlets. The divider is further configured to direct another portion of the inflowing air toward the secondary power source. After cooling the secondary power source, inflowing air exits the power system cavity via the one or more air outlets.

Aspects of the present disclosure are directed to a machine comprising a machine body, an implement movably coupled to the machine body, and a power system. The power system includes a power electronics module, one or more rechargeable batteries, a genset, and a liquid cooling system. The liquid cooling system includes a heat exchanger, a first cooling loop, and a second cooling loop. The first cooling loop and the second cooling loop circulate through the heat exchanger. The second cooling loop is configured to receive heat from the one or more rechargeable batteries.

Aspects of the present disclosure include a machine comprising a power system and a cooling system. The power system includes one or more rechargeable batteries, a secondary power source, and a power electronics module. The cooling system includes an air cooling system including one or more fans and a divider. The divider is positioned between the secondary power source and the power electronics module. The cooling system further includes a liquid cooling system including a heat exchanger, a first cooling loop fluidly connected to the heat exchanger, and a second cooling loop fluidly connected to the heat exchanger. The first cooling loop is configured to receive heat from the power electronics module. The second cooling loop is configured to receive heat from the one or more rechargeable batteries. At least one of the one or more fans is configured to remove heat from the power electronics module. At least one fan of the one or more fans is configured to remove heat from the secondary power source.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 is an illustration of an exemplary machine, according to aspects of the disclosure.

FIG. 2A is a perspective view of a power system of the machine of FIG. 1, and FIG. 2B is a side view of the power system of the machine of FIG. 1.

FIG. 3A is a side view of a power electronics module and a divider for the power system of FIGS. 2A and 2B, and FIG. 3B is a perspective view of the power electronics module and the divider for the power system of FIGS. 2A and 2B.

FIG. 4 depicts a schematic diagram of a cooling system of the power system of FIGS. 2A and 2B.

### DETAILED DESCRIPTION

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value.

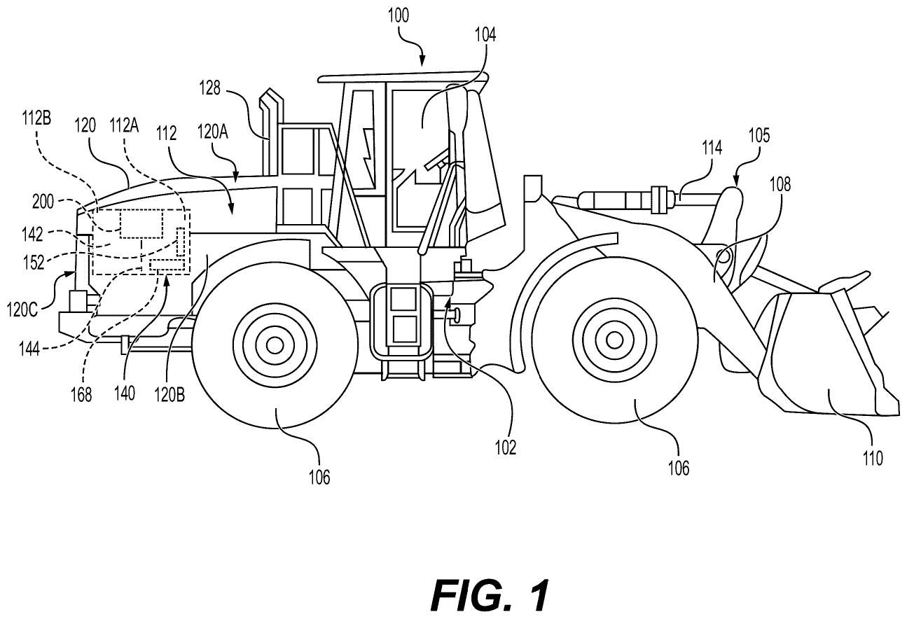

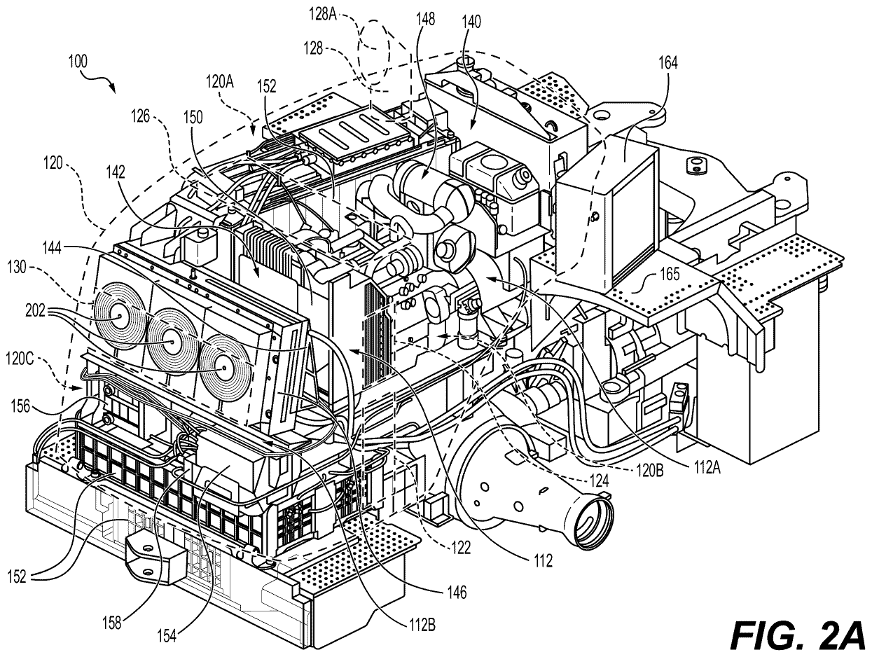

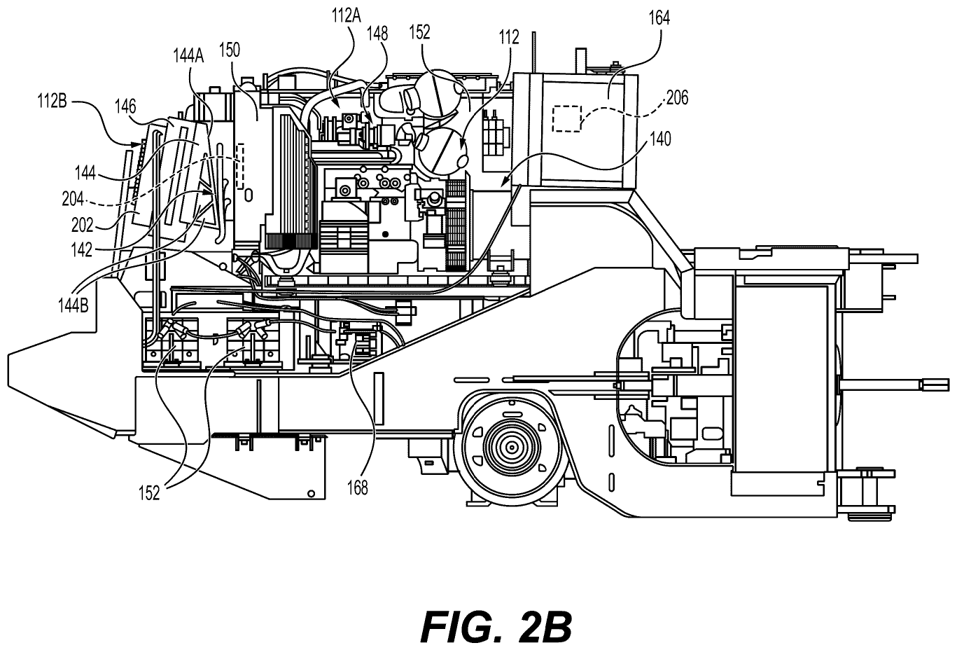

FIG. 1 depicts an exemplary machine, for example, a wheel loader 100, including a plurality of wheels 106. Although the machine depicted in FIG. 1 is a wheel loader, machine 100 may be any of the types of machines described above. Machine 100 includes a machine body 102, which may include an operator station or cab 104, an engine housing, engine bay, or cavity 112 (referred to herein at cavity 112), and a prime mover or power system 140, including one or more rechargeable batteries 152 (FIGS. 2A-2B). The one or more batteries 152 may power or energize a motor 168 or other components of machine 100. In some aspects, machine 100 may be fully electric, for example, machine 100 may be fully powered by the one or more batteries 152 of power system 140. Although not shown, machine 100 may be semi-electric (e.g., hybrid), and power system 140 may include a secondary power source, for example, an engine, a genset, a fuel cell, etc. Cavity 112 may be configured (e.g., sized, shaped, or otherwise capable of) contain one or more components of the power system 140 such as one or more components of the secondary power source. The secondary power source may help power or otherwise energize motor 168 to drive wheels 106 or power one or more additional components of machine 100. For example, the secondary power source may be used to recharge batteries 152 during operation of machine 100. Additionally, in some aspects, the one or more batteries 152 may be removable, for example, to be charged away from machine 100, to be easily replaced with one or more charged batteries 152 to extend the work time of machine 100. In other aspects, the one or more batteries 152 may be charged via a charger (e.g., a plug-in charger) during downtime for machine 100.

Machine 100 may be a vehicle or machine that may be electric or semi-electric (e.g., at least partially electric). Retrofitting existing non-electric machines (e.g., fuel-burning) to electric or partially electric machines helps to provide ecological and environmental benefits, increase fuel efficiency, and increase the expected useful life of existing machines, which potentially would have otherwise been required to be retired or scrapped if retrofitting proved too costly. In non-electric vehicles, power system 140, including one or more batteries 152, may be installed in addition to or in replacement of a fuel-burning engine. However, power system 140 may be installed in addition to or in replacement of a power system of partially electric machine, such as a fuel-burning engine or electric power source, or a power system of a fully-electric machine, such as an electric power source.

Machine 100 may include an implement assembly 105. Implement assembly 105 may be movably coupled to machine body 102 or another component of machine 100. The implement assembly 105 may include one or more arms 108 and a bucket 110 that may be coupled to an end of arm(s) 108. Although not shown, bucket 110 may also be a different work implement, such as a fork, grapple, etc., and, in some aspects, the work implement may be interchangeable. One or more hydraulic arms (e.g., hydraulic arm 114) may be a part of or otherwise coupled to one or more portions of implement assembly 105 to raise and lower arm 108 and bucket 110, and to tilt bucket 110 toward or away from machine 100. Machine 100 may include ground surface engaging devices, such as wheels 106 that support machine body 102 and are powered by the power system 140 (e.g., via motor 168). In another aspect, machine 100 may instead have tracks (not shown).

Power system 140, including one or more batteries 152, may be positioned in a rear portion of machine 100, and, for example, may be positioned in cavity 112. One or more components of power system 140 may be modular such that one or more components of power system 140 may be installed in different locations within cavity 112 or about machine 100. Machine 100 may include a hood 120 to cover or enclose power system 140 within cavity 112. Alternatively, power system 140 may be positioned anywhere on machine 100.

As shown in FIG. 1, power system 140 may include a cooling system 200 configured to help direct or promote airflow across or around various portions of power system 140, which may help to remove heat from the power system 140 and cavity 112. Power system 140 include a central chamber 142 for receiving inflowing air and a divider 144 within central chamber 142 configured to direct some airflow in one direction and direct some airflow in another, different direction. Explained differently, divider 144 or central chamber 142 may divide the power system cavity 112 into a front portion 112A and a rear portion 112B. For example, divider 144 may direct some air toward a rear end of machine 100 and may direction some air toward a front end of machine 100. The cooling system 200 is described in greater detail below.

As shown in FIGS. 2A and 2B, power system 140 may include a secondary power source, for example, a genset 148. Genset 148 may include or otherwise be coupled to a radiator 150. Genset 148 and radiator 150 may be positioned within the front portion 112A of cavity 112. Radiator 150 may be positioned to the rear of the genset 148. The genset 148 may be a diesel-burning genset, a propane-burning genset, a gasoline-burning genset, or a natural gas-burning genset. Although, the secondary power source is discussed as genset 148, in other aspects, the secondary power source may be a hydrogen powered engine, a fuel cell, or other known power systems. Genset 148 or radiator 150 may include a fan 204 (FIG. 2B), such as an electric fan. As discussed below, fan 204 may be a part of or otherwise in communication with cooling system 200. Power system 140 may further include a power electronics module 146. Power electronics module 146 may be positioned within the rear portion 112B of cavity 112. Central chamber 142 and divider 144 may be positioned between (e.g., along a longitudinal axis of machine 100) radiator 150 and power electronics module 146. Power electronics module 146 may include a fan 202 (FIG. 2A), such as an electric fan. For example, as shown, power electronics module 146 may include a plurality of fans 202. As discussed below, fan 202 may be a part of or otherwise in communication with cooling system 200.

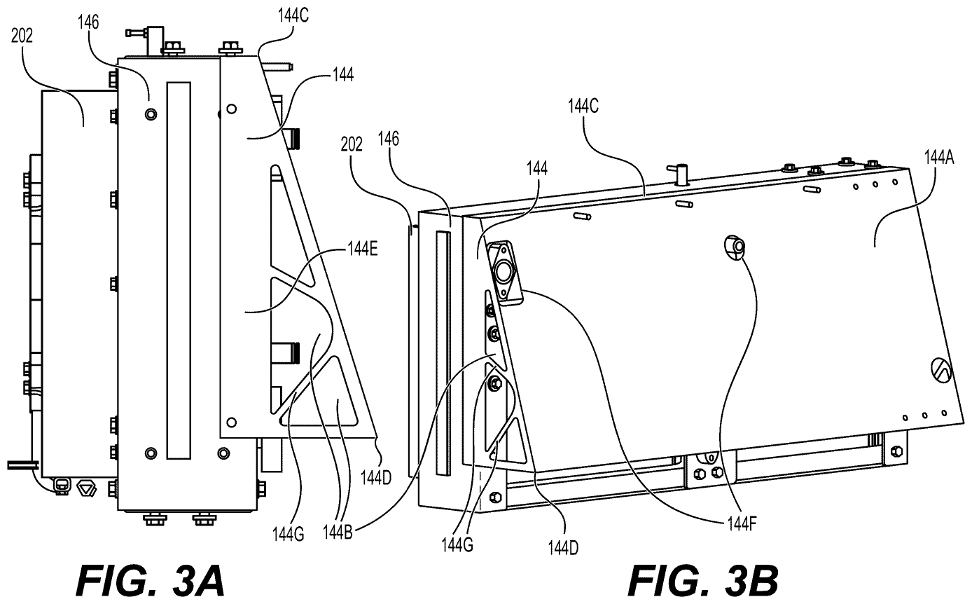

As shown in FIGS. 3A and 3B, divider 144 may be coupled (e.g., affixed or removably attached) to power electronics module 146. For example, divider 144 may be coupled to a front-facing surface (e.g., front end of machine 100 facing) of power electronics module 146. In some embodiments, instead of being coupled to power electronics module 146, divider 144 may be coupled to other components of power system 140 or machine body 102. Divider 144 may include a planar, angled surface 144A. Angled surface 144A may extend at an angle relative to the front-facing surface of the power electronics module 146 from a first end 144C at a top end of divider 144 to a second end 144D at a bottom end of divider 144. In other words, the second end 144D of angled surface 144A may be nearer the front end of machine 100 than the first end 144C of angled surface 144A. As shown in FIG. 3B, angled surface 144A may include one or more apertures 144F, which may be configured to receive one or more cables, conduits, or wires of power electrics module 146 extending therethrough. Divider 144 may include one or more vertical supports 144E, which may be coupleable to power electronics module 146. At least a portion of the surface of the one or more vertical supports 144E may include or otherwise form a plurality of openings or vents 144B defined therethrough. One or more beams, bars, or supports 144G may be positioned between adjacent vents 144B of vertical supports 144E. A rear portion of vertical supports 144E may be fixedly or removably coupled to power electronics module 146. Vents 144B may facilitate airflow through the side surfaces of divider 144. As shown in FIG. 2B, angled surface 144A may be angularly disposed within the central chamber 142.

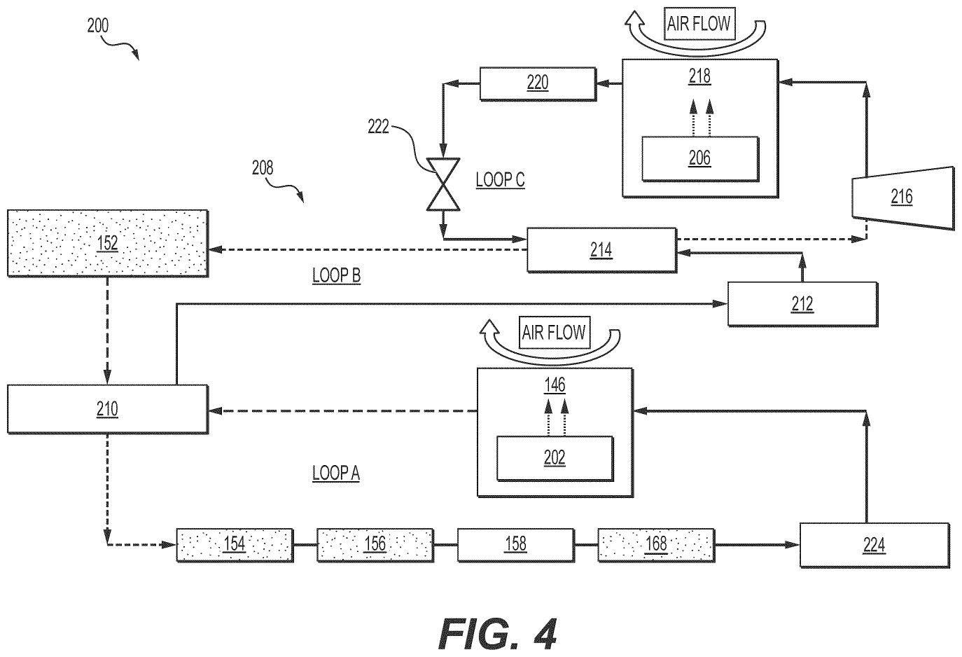

Referring back to FIGS. 2A and 2B, power system 140 may include a battery thermal management system (BTMS 164) to regulate the temperature of the one or more batteries 152, for example, to help prevent deterioration or improve performance. BTMS 164 may be positioned within or outside cavity 112. For example, BTMS 164 may be positioned within or adjacent to the front portion 112A of cavity 112. BTMS 164 may be positioned above and supported by a mounting 165 affixed to machine 100 or machine body 102. A planar surface of mounting 165 may extend away from or into cavity 112 and be configured to support BTMS 164. One or more components of BTMS 164 may be modular. BTMS 164 may include a fan 206 (FIGS. 2B, 4) such as an electric fan, and a condenser 218 (FIG. 4). As shown in FIG. 4 and discussed below, condenser 218 and fan 206 may be a part of or otherwise in communication with cooling system 200. As will be discussed below, BTMS 164 may include one or more of an evaporator 214, a compressor 216, a dryer 220, an expansion valve 222, and a pump. Although not shown, BTMS 164 may further include one or more of a radiator or a chiller. One or more components of BTMS 164, including condenser 218, fan 206, the radiator, and the chiller, may be positioned within a casing of BTMS 164, anywhere within cavity 112, or anywhere about machine body 102. One or more components of BTMS 164 may be positioned away from one or more other components of BTMS 164. For example, some components of BTMS 164 may be positioned within front portion 112A, some components of BTMS 164 may be positioned within rear portion 112B, and some components may be positioned elsewhere along machine 100. In these aspects, the components of BTMS 164 may be distributed throughout the casing (not shown), cavity 112, or otherwise on machine body 102, which may help to use the available space on or within machine 100 during a retrofitting procedure.

Power system 140 may further include a power distribution unit (PDU 154), a DC-DC converter 156, an AC-DC inverter 158, a motor 168, and an on-board charging station (e.g., charger (not shown)) PDU 154, converter 156, and inverter 158 may be positioned within the rear portion 112B of the cavity 112 or below power electronics module 146. Motor 168 may include a motor inverter (not shown). Motor 168 may be positioned within the front portion 112A of the cavity 112. Motor 168 may include appropriate connections to be coupled to a transmission of machine 100. According to some aspects, power system 140 may include a plurality of motors 168. For example, power system 140 may include one motor 168 for driving the transmission of machine 100 and another motor 168 for driving other components of machine 100, such as brakes, hydraulics, steering, and accessory devices. A charger (not shown) may be positioned to the rear of central chamber 142 below or within the rear portion 112B. According to some aspects, power system 140 may also include a gearbox, for example, coupled to an inverter and having appropriate connections to a transmission of machine 100.

The one or more batteries 152 of power system 140 may be positioned within cavity 112. For example, the one or more batteries 152 may include three batteries 152. One or more of the batteries 152 may be positioned within the front portion 112A of the cavity 112. For example, one or more of batteries 152 may be adjacent to genset 148. Further, one or more of batteries 152 may be positioned within the rear portion 112B of the cavity 112. For example, one or more batteries 152 may be positioned under one or more of power electronics module 146, PDU 154, converter 156, and inverter 158. The one or more batteries 152 may be lithium ion phosphate batteries, however, batteries 152 may be any type of battery for powering electric or partially electric vehicles or machines. Each of the one or more batteries 152 may include a plurality of battery cells (e.g., a battery string).

FIG. 2A depicts hood 120 of machine 100 as being transparent and in dashed line. Hood 120 may include one or more openings for facilitating the exchange of air between the cavity 112 and an environment external to machine 100. Hood 120 may include one or more openings (e.g., inlets) for facilitating airflow into cavity 112 or central chamber 142 from the environment. For example, hood 120 may include at least one top opening 126 (e.g., top inlet) defined through a top surface 120A of hood 120. Further, hood 120 may include at least two side surfaces 120B positioned opposite one another relative to top surface 120A of hood 120. Hood 120 may include a first side opening 122 and a second side opening 124 (e.g., side inlets) defined through each side surface. Inflowing air may enter the cavity 112 or central chamber 142 via any of openings 122, 124, 126.

Still referring to FIG. 2A, hood 120 may include one or more openings (e.g., outlets) for facilitating airflow out of cavity 112 to the environment. For example, hood 120 may include at least one exhaust conduit 128 extending from top surface 120A of hood 120. Exhaust conduit 128 may be in fluid communication with cavity 112 and include at least one exhaust opening 128A. Further, hood 120 may include at least one rear opening 130 defined through a rear surface 120C of hood 120. Outflowing air may exit cavity 112 via one or more of rear opening 130 or exhaust opening 128A.

An exemplary a schematic diagram of cooling system 200 of the power system 140 is depicted in FIG. 4. Cooling system 200 may remove or draw heat away from power system 140 or cavity 112 via an air cooling system and a liquid cooling system 208. The air cooling system may direct airflow (depicted as airflow arrows in FIG. 4) through, along or otherwise around various components of power system 140 and the liquid cooling system 208 to help remove or draw heat away from the components. The air cooling system may include a plurality of fans. For example, the air cooling system may include fan 202 (herein first fan 202) configured to pull or otherwise urge air through, along or otherwise around power electronics module 146. Further, the air cooling system may include fan 204 (herein second fan 204) configured to pull or urge air through, along or otherwise around genset 148 and radiator 150. The air cooling system may also include fan 206 (herein third fan 206) configured to pull or urge air through, along or otherwise around BTMS 164. Each of fans 202, 204, 206 may comprise a plurality of fans. For example, as shown in FIG. 2A, first fan 202 may include three fans 202. Although fans 202, 204, 206 are discussed as being configured to pull or urge air, it should under that any of fans 202, 204, 206 may be configured to push, pull, or urge air. For example, fans 202, 204, 206 may be configured to push or pull air based on a position of the fan 202, 204, 206 relative the component of power system 140 that the respective fan is configured to urge air through, along or otherwise around. Stated another way, each of fans 202, 204, 206 may be configured to create negative pressure. For example, first fan 202 and second fan 204 may help to create negative pressure within central chamber 142 to draw in airflow from the environment via openings 122, 124, 126 and draw air flow from below central chamber 142. Moreover, the negative pressure within central chamber 142 may draw in airflow from other areas of cavity 112. In some examples, inflowing air from openings 122, 124, 126 may in flow into other areas of cavity 112 in addition to central chamber 142. The negative pressure within central chamber 142, created by fans 202, 204, may help to draw air that has flowed through openings 122, 124 into other areas of cavity 112 from those other areas of cavity 112 into central chamber 142.

During operation, the air cooling system of cooling system 200 may pull or urge air, from the environment into central chamber 142 via side openings 122, 124 and top opening 126. Additionally, the air cooling system of cooling system 200 may pull or urge air from below the central chamber 142 or below machine body 102 into central chamber 142 during operation. The divider 144 may direct some airflow to the front portion 112A of the cavity 112 and may direct some airflow into central chamber 142 to the rear portion 112B of the power system cavity 112. Further, first fan 202 may be configured to pull or urge air from a portion of central chamber 142 to the rear of angled surface 144A. Second fan 204 may be configured to pull or urge air from a portion of central chamber 142 to the front of angled surface 144A.

Angled surface 144A of divider 144 may help to direct inflowing air from the top opening 126 and side openings 122, 124 towards the front portion 112A of the cavity 112. Further, the second fan 204 may pull or urge the front-directed airflow through the radiator 150 of genset 148 and then into the front portion 112A of the cavity 112. A portion of the airflow within the front portion 112A may help to remove heat from genset 148 (e.g., one or more components of genset 148), and a portion of the airflow may exit the front portion 112A via opening 128A of the exhaust conduit 128. For example, warmer (e.g., less dense) airflow near the top of the front portion 112A may exit via opening 128A, while cooler (e.g., more dense) airflow further away from the top of the front portion 112A may cool one or more components of genset 148. It should be understood that as the airflow passes through or along radiator 150 and genset 148, the air may help to remove heat from radiator 150 and genset 148. Airflow within the front portion 112A may be drawn through, along, or otherwise around BTMS 164 via third fan 206, which may help to remove heat from BTMS 164. For example, airflow may be pulled or urged through BTMS 164 via third fan 206 to remove heat from the condenser 218 of BTMS 164. After the airflow passes through, along or otherwise around BTMS 164, the airflow may exit BTMS 164 or cavity 112 to the environment via one or more openings (not shown).

The angled surface 144A of divider 144 may help to direct inflowing air from below central chamber 142 or machine body 102 and side openings 122, 124 towards the rear portion 112B of the cavity 112. Airflow from side openings 122, 124 may enter the portion of the central chamber 142 to the rear of angled surface 144A via vents 144B. Further, first fan 202 may pull or urge the rear-directed airflow through, along, or otherwise around various portions of power electronics module 146 to help remove heat from power electronics module 146. After passing through, along, or otherwise around power electronics module 146, the rear-directed airflow may exit the rear portion 112B to the environment via rear opening 130.

Still referring to FIG. 4, as mentioned above, the air cooling system may be configured to remove heat from one or more components of liquid cooling system 208 of cooling system 200. Liquid cooling system 208 may include a heat exchanger 210. For example, heat exchanger 210 may be a liquid-to-liquid heat exchanger such as, but not limited to, a water-to-water heat exchanger. Liquid cooling system 208 may include one or more conduits for circulating liquid (e.g., water) and forming one or more cooling loops, for example, a first loop A and a second loop B. Liquid cooling system 208 may further include one or more conduits for circulating liquid (e.g., refrigerant) and forming at least one other loop, for example, a third loop C. Liquid cooling system 208 may include one or more pumps configured to circulate liquid within the loops. For example, liquid cooling system 208 may include a first pump 212 and a second pump 224. First pump 212 may be in fluid communication with the first loop A, and second pump 224 may be in fluid communication with second loop B. Liquid cooling system 208 may further include evaporator 214 of BTMS 164. Loops B and C may each be fluidly connected to evaporator 214, for example, such that fluid within each of loops B and C may circulate, flow, or otherwise pass through the evaporator 214 and the liquid within respective loops B and C may be cooled while passing through evaporator 214. In some aspects, each of loops A, B, and C are fluidly isolated from one another and may pass through one or more components of power system 140 or cooling system 200. In some other aspects, first loop A and second loop B are in fluid communication with one another, but fluidly isolated from third loop C.

First loop A may pass through, along, or otherwise around one or more portions of one or more of charger (not shown), converter 156, inverter 158, motor 168, pump 212, power electronics module 146, and first fan 202. In one example, relatively cold water may flow out of heat exchanger 210 and pass through, along, or otherwise around one or more portions of one or more of charger (not shown), converter 156, inverter 158, and motor 168. Although FIG. 4 depicts water flowing through, along, or otherwise around one or more portions of charger (not shown), then converter 156, then inverter 158, and then motor 168, it should be understood that water may flow through, along, or otherwise around one or more portions of these components in any order. As the water passes through, along, or otherwise around one or more portions of charger (not shown), converter 156, inverter 158, and motor 168, heat may be transferred from the respective component to the water flowing within first loop A to help cool the component and heat the water, such that the water is relatively hot. After passing through charger (not shown), converter 156, inverter 158, and motor 168, the relatively hot water may be pumped via first pump 212 and passes through the power electronics module 146 or first fan 202. While passing through the power electronics module 146 or first fan 202, airflow (e.g., rear-directed airflow from central chamber 142) may help to remove heat from the water flowing within first loop A to cool the water such that it is relatively warm. After passing through the power electronics module 146 or first fan 202, the relatively warm water may enter the heat exchanger 210 and be cooled, such that the water is relatively cold before being recirculated through first loop A.

Second loop B may pass through, along, or otherwise around one or more portions of one or more of pump 224, evaporator 214, and one or more batteries 152. For example, relatively hot water may flow out of heat exchanger 210 and be pumped via pump 224 through evaporator 214. While flowing through evaporator 214, the relatively hot water within loop B may be cooled, such that the relatively hot water is relatively cold water after passing through evaporator 214. The relatively cold water may then flow through, along, or otherwise around one or more batteries 152 to transfer heat from the one or more batteries 152 to the water, such that the water is relatively warm after passing through the one or more batteries 152. The relatively warm water may enter the heat exchanger 210 and be heated such that it is relatively hot before being recirculated through second loop B.

Liquid cooling system 208 may further include one or more components of BTMS 164, such as compressor 216, dryer 220, and expansion valve 222. As mentioned, a refrigerant may be circulated within third loop C. Relatively cold refrigerant may flow from evaporator 214 and into compressor 216. Compressor 216 may help to decrease the volume of the refrigerant, increase the temperature of the refrigerant, such that the refrigerant is relatively hot, and pump the refrigerant. The relatively hot refrigerant may pass through condenser 218. While passing through condenser 218 of BTMS 164, airflow (e.g., front-directed airflow from central chamber 142) may remove heat from the refrigerant flowing within third loop C to help cool the refrigerant, but the refrigerant may remain relatively hot. The relatively hot refrigerant may then pass through dryer 220. Dryer 220 may be configured to remove moisture or water from the refrigerant. The refrigerant leaving dryer 220 may be relatively hot. The relatively hot refrigerant may pass through expansion valve 222 before flowing into evaporator 214. While passing through evaporator 214, heat may be removed from the refrigerant, such that the refrigerant is relatively cold before being recirculated through third loop C. According to some aspects, refrigerant leaving condenser 218 may be relatively warm. In aspects where refrigerant is relatively warm when the refrigerant leaves condenser 218, the relatively warm refrigerant may pass through dryer 220, and then expansion valve 222 before flowing into evaporator 214.

### Industrial Applicability

The disclosed aspects of the cooling system 200 of the present disclosure may be applied to any electric or at least partially electric machine or vehicle, such as a semi-electric wheel loader. During operation of an exemplary electric or semi-electric machine 100, one or more components of a power system 140 of the machine 100 may generate heat within an engine bay (e.g., power system cavity 112) of the machine 100. The disclosed cooling system 200 may help to remove heat from one or more components of the power system and the engine bay 112. As discussed above, cooling system 200 includes a liquid cooling system 208 that helps to remove heat from one or more components of the power system 140. The cooling system 200 also includes an air cooling system that helps to remove heat from one or more components of the power system 140 and from one or more components of the liquid cooling system 208.

Power system 140, including cooling system 200, may be installed (e.g., retrofitted) into fuel-burning, partially electric, and fully electric machines or vehicles. Retrofitting existing non-electric machines to electric or partially electric machines may help to provide ecological and environmental benefits, increase fuel efficiency, and increase the expected useful life of existing machines, which potentially would have otherwise been required to be retired or scrapped if retrofitting proved too costly. As discussed, one or more components of power system 140 may be modular so that one or more components of power system 140 may be positioned within cavity 112, front portion 112A, rear portion 112B, or otherwise on machine body 100. For example, the components of BTMS 164 may be distributed throughout the casing (not shown) of BTMS 164, cavity 112, or otherwise on machine body 102, which may help to use the available space on or within machine 100 during a retrofitting procedure. Moreover, cooling system 200 may further help to extend the useful life and performance of one or more components of the machine. For example, cooling system 200 may help to remove heat or chill one or more batteries 152. Thus, in addition to the other features of power system 140, power system 140 may help to allow for convenient, effective, and cost-effective retrofitting of existing non-electric machines to electric or partially electric machines.

As discussed above, the air cooling system, including the various inlets (e.g., side openings 122, 124, and top opening 126), outlets (e.g., exhaust conduit 128, and rear opening 130), fans (e.g., fans 202, 204, 206), and divider 144, may help to provide a divorced or separated air feed. In these aspects, some inflowing air (e.g., from the environment) is directed to one or more components in a rear portion 112B of the engine bay 112. Further, some inflowing air is directed to one or more components in a front portion 112A of the engine bay 112. Divider 144 may help to thermally isolate a portion of engine bay 112 from another portion of engine bay 112. For example, divider 144 may help to, at least partially, thermally isolate rear portion 112B from front portion 112A. At least partial thermal isolation between rear portion 112B and front portion 112A may help prevent damage to temperature-sensitive components of power system 140. Further, the air cooling system may help to easily and quickly cool components within rear portion 112B.

As mentioned above, the liquid cooling system 208 of the cooling system 200 may help to remove heat from one or more components of machine 100. The water-to-water heat exchanger 210 of the disclosed cooling system 200 may leverage the heat transfer efficiency of water as a coolant. Moreover, using water as a coolant may be more cost-effective or may help to allow for the machine 100 to be operated at a wider range of external temperatures. The batteries of electric and semi-electric machines may exhibit improved useful life and performance during operation of the machine when battery temperatures are regulated to not exceed or fall below predetermined temperature thresholds, dependent on the specification of the battery. Accordingly, the disclosed cooling system 200 may increase the useful life of the one or more batteries 152 and other temperature-sensitive components of the machine 100.

The disclosed cooling system 200 may be implemented in existing and future machines. In particular, the disclosed cooling system 200 may be implemented in existing machines (e.g., in a retrofitting procedure) that have been converted from fuel-burning machines to at least partially electric machines without regard to the type of fuel burned by a secondary power source of the machine, such as the genset or engine.

It will be apparent to those skilled in the art that various modifications and variations can be made to the disclosed system without departing from the scope of the disclosure. Other embodiments of the system will be apparent to those skilled in the art from consideration of the specification and practice of the system disclosed herein. It is intended that the specification and examples be considered as exemplary only, with a true scope of the disclosure being indicated by the following claims and their equivalents.

What is claimed is:

1. A machine comprising:
a machine body;
a hood coupled to the machine body and including:
one or more air inlets; and
one or more air outlets;
a power system including:
one or more batteries;
a power electronics module; and
a secondary power source;
a power system cavity configured to receive the power system, the power system cavity is defined between the hood and the machine body;
a central chamber defined between the power electronics module and the secondary power source, wherein the central chamber receives inflowing air via the one or more inlets; and
a divider positioned within the central chamber;
wherein the divider is configured to direct a portion of the inflowing air toward the power electronics module to cool the power electronics module,
wherein, after cooling the power electronics module, inflowing air exits the power system cavity via the one or more air outlets,
wherein the divider is configured to direct another portion of the inflowing air toward the secondary power source,
wherein, after cooling the secondary power source, inflowing air exits power system cavity via the one or more air outlets.

2. The machine of claim 1, wherein the divider includes a surface angularly disposed within the central chamber, wherein the divider further includes one or more vertical supports couplable to the power electronics module, wherein one or more vents are defined through a surface of each vertical support.

3. The machine of claim 2, wherein the hood includes a top inlet defined through a top surface of the hood and a side inlet defined through a side surface of the hood, wherein the one or more vents are configured to receive airflow from the side inlet of the hood.

4. The machine of claim 3, wherein the divider is configured to direct inflowing air from the top inlet toward the secondary power source.

5. The machine of claim 2, wherein the divider is coupled to one or more portions of the power electronics module.

6. The machine of claim 1, further comprising: one or more fans configured to draw air from the central chamber around the power electronics module.

7. The machine of claim 1, further comprising: one or more first fans configured to draw air from the central chamber into a portion of the power system cavity containing one or more components of the secondary power source.

8. The machine of claim 7, further comprising: a battery thermal management system and one or more second fans, wherein the one or more second fans are configured to draw air from the portion of the power system cavity containing one or more components of the secondary power source through or around the battery thermal management system.

9. A machine comprising:
a machine body;
an implement movably coupled to the machine body;
a power system including:
a power electronics module;
one or more rechargeable batteries; and
a genset; and
a liquid cooling system including:
a heat exchanger;
a first cooling loop; and
a second cooling loop; and
wherein, the first cooling loop and the second cooling loop circulate through the heat exchanger;
wherein, the second cooling loop is configured to receive heat from the one or more rechargeable batteries.

10. The machine of claim 9, further comprising one or more of a converter, an inverter, and a motor, wherein the first cooling loop is configured to receive heat from one or more of the converter, the inverter, and the motor.

11. The machine of claim 10, wherein the first cooling loop is configured to receive heat from the power electronics module.

12. The machine of claim 9, wherein the power system further includes an air cooling system including one or more fans configured to remove heat from at least one of the genset and the power electronics module.

13. The machine of claim 9, wherein heat exchanger is a water-to-water heat exchanger.

14. A machine comprising:
a power system including:
one or more rechargeable batteries,
a secondary power source, and
a power electronics module;
a cooling system including:
an air cooling system including one or more fans and a divider, wherein the divider is positioned between the secondary power source and the power electronics module; and
a liquid cooling system including:
a heat exchanger,
a first cooling loop fluidly connected to the heat exchanger,
a second cooling loop fluidly connected to the heat exchanger;
wherein the first cooling loop is configured to receive heat from the power electronics module,
wherein the second cooling loop is configured to receive heat from the one or more rechargeable batteries,
wherein at least one of the one or more fans is configured to remove heat from the power electronics module,
wherein at least one fan of the one or more fans is configured to remove heat from the secondary power source.

15. The machine of claim 14, wherein the liquid cooling system further comprises a third cooling loop and an evaporator, and wherein the second cooling loop and third cooling loop each circulate through, along or otherwise around the evaporator.

16. The machine of claim 15, wherein the power system further comprises a battery thermal management system having a condenser, and wherein a fan of the one or more fans is configured to remove heat from the condenser.

17. The machine of claim 16, wherein the third cooling loop circulates through, along or otherwise around the condenser of the battery thermal management system.

18. The machine of claim 14, wherein a fan of the one or more fans is configured to remove heat from the power electronics module.

19. The machine of claim 14, further comprising: one or more of a converter, an inverter, and a motor, and wherein the first cooling loop circulates through, along or otherwise around one or more of the converter, the inverter, and the motor.

20. The machine of claim 14, wherein the heat exchanger is a water-to-water heat exchanger.
